(19) United States
(12) Patent Application Publication
(10) Pub. No.: US 2022/0341442 A1
(43) Pub. Date: Oct. 27, 2022

(54) NON-ELECTRONIC CONTROL USING PNEUMATICALLY-ACTUATED TRANSISTOR LOGIC

(71) Applicant: President and Fellows of Harvard College, Cambridge, MA (US)

(72) Inventors: Lukas WILLE, Hamburg (DE); Markus P. NEMITZ, Cambridge, MA (US); Dylan PATHIRAJA, Cambridge, MA (US); Christoffer Karl ABRAHAMSSON, Cambridge, MA (US)

(21) Appl. No.: 17/761,728

(22) PCT Filed: Sep. 18, 2020
(86) PCT No.: PCT/US20/51576

§ 371 Date: Mar. 18, 2022

Related U.S. Application Data
(60) Provisional application No. 62/902,125, filed on Sep. 18, 2019.

(51) Int. Cl. F15B 15/10; F15B 21/08

(52) U.S. Cl. CPC F15B 15/103; F15B 21/08; B25J 9/142

(57) ABSTRACT

In one aspect, system to form a pneumatically-actuated transistor logic includes a first deformable conduit; a first extensible bladder disposed at a first location along the first conduit; a first structure in proximity with the first bladder and configured to constrain expansion of the first bladder; wherein the first structure and the first bladder are configured to allow flow of fluid through the first conduit when the first bladder is in a first state and to prevent flow of fluid through the first conduit when the first bladder is in a second state.

### RELATED APPLICATIONS

This application claims the benefit of priority to co-pending U.S. Provisional Application Ser. No. 62/902,125, filed Sep. 18, 2019, the contents of which is incorporated by reference.

### COPYRIGHT NOTICE

This patent disclosure may contain material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF THE INVENTION

This application relates to non-electronic control of soft actuators. In particular, this application relates to pneumatically-actuated transistor logic.

### BACKGROUND OF THE TECHNOLOGY

Soft robots are often controlled by hard valves and electronics. Soft robots have complex supporting infrastructures including microcontrollers interfaced with actuation circuitry to control the on-off switching of hard valves or pneumatic flow. Complex fabrication processes of soft digital logic gates based on soft bistable valves limit the mass-manufacture and integration of soft logic gates in large numbers, and low switching pressures (˜10 kPa) and actuation frequencies (˜1 Hz) limit the utility of soft logic gates as a replacement for electronic controls. There is a lack of logic gates that are (i) easy to manufacture, (ii) easy to integrate, (iii) operate at high pressures, and (iv) operate at high frequencies.

### SUMMARY

In one aspect, system to form a pneumatically-actuated transistor logic includes a first deformable conduit; a first extensible bladder disposed at a first location along the first conduit; a first structure in proximity with the first bladder and configured to constrain expansion of the first bladder; wherein the first structure and the first bladder are configured to allow flow of fluid through the first conduit when the first bladder is in a first state and to prevent flow of fluid through the first conduit when the first bladder is in a second state.

In some embodiments, the first state of the first bladder is an inflated state and the second state of the first bladder is an uninflated state.

In some embodiments, the first state of the first bladder is an uninflated state and the second state of the first bladder is an inflated state.

In some embodiments, the system includes a first input to the first bladder.

In some embodiments, the system is configured to apply a first pressure to the first bladder to actuate between the first state of the first bladder and the second state of the first bladder.

In some embodiments, the first pressure is a positive pressure.

In some embodiments, the first pressure is a negative pressure.

In some embodiments, the system includes a pulldown resistor.

In some embodiments, the pulldown resistor is fluidically connected to the first bladder.

In some embodiments, the pulldown resistor is fluidically connected to the first conduit.

In some embodiments, the system includes a foam spring.

In some embodiments, the first structure is configured to deform the first conduit when the first bladder is in the second state.

In some embodiments, the first structure is configured to squeeze, kink, or twist the first conduit.

In some embodiments, the first structure is stiffer than the first conduit.

In some embodiments, the first structure includes a force concentrating feature.

In some embodiments, the first bladder is elastomeric.

In some embodiments, the first bladder includes a material selected from the group consisting of vulcanized rubber, silicone elastomer, latex, polyurethanes, thermoplastic polyurethane, textiles, textiles with thermo-coatings, foams and combinations thereof.

In some embodiments, the first structure is non-extensible.

In some embodiments, the first structure is rigid.

In some embodiments, the first structure includes a material selected from the group consisting of poly vinyl chloride, polyurethane, nylon, polyethylene, polypropylene, polyurea, foams, textiles, paper, coated paper, kirigami, origami and combinations thereof.

In some embodiments, the first conduit is non-extensible.

In some embodiments, the first conduit includes a material selected from the group consisting of polyethylene, polystyrene, polymethyl methacrylate, polyethylene terephthalate, polytetrafluoroethylene, high density foam, compressed polyester, coated textiles, laminated fabrics, and combinations thereof.

In some embodiments, the system includes a second deformable conduit, wherein the first extensible bladder is disposed at a second location along a second conduit; wherein the first structure and the first extensible bladder are configured to prevent flow of fluid through the second conduit when the first bladder is in a first state and to allow flow of fluid through the second conduit when the first bladder is in a second state.

In some embodiments, the system includes a pulldown resistor fluidically connected to the second conduit.

In some embodiments, the first structure is configured to deform the second conduit when the first bladder is in the first state.

In some embodiments, the first structure is configured to squeeze, kink, or twist the second conduit.

In some embodiments, the first structure is stiffer than the second conduit.

In some embodiments, the second conduit is non-extensible.

In some embodiments, the second conduit includes a material selected from the group consisting of polyethylene, polystyrene, polymethyl methacrylate, polyethylene terephthalate, polytetrafluoroethylene, high density foam, compressed polyester, coated textiles, laminated fabrics, and combinations thereof.

In some embodiments, the system includes a second extensible bladder is disposed at a second location along the first conduit; a second structure in proximity with the second bladder and configured to constrain expansion of the second bladder; wherein the second structure and the second bladder are configured to allow flow of fluid through the first conduit when the second bladder is in a first state and to prevent flow of fluid through the first conduit when the second bladder is in a second state.

In some embodiments, the first state of the second bladder is an inflated state and the second state of the second bladder is an uninflated state.

In some embodiments, the first state of the second bladder is an uninflated state and the second state of the second bladder is an inflated state.

In some embodiments, they system includes a second input to the second bladder.

In some embodiments, the system is configured to apply a second pressure to the second bladder to actuate between the first state of the second bladder and the second state of the second bladder.

In some embodiments, the second pressure is a positive pressure.

In some embodiments, the second pressure is a negative pressure.

In some embodiments, includes a pulldown resistor fluidically connected to the second bladder.

In some embodiments, the second structure is configured to deform the first conduit when the second bladder is in the second state.

In some embodiments, the second structure is configured to squeeze, kink, or twist the first conduit.

In some embodiments, the second structure is stiffer than the first conduit.

In some embodiments, the second structure includes a force concentrating feature.

In some embodiments, the second bladder is elastomeric.

In some embodiments, the second bladder includes a material selected from the group consisting of vulcanized rubber, silicone elastomer, latex, polyurethanes, thermoplastic polyurethane, textiles, textiles with thermo-coatings, foams and combinations thereof.

In some embodiments, the second structure is non-extensible.

In some embodiments, the second structure is rigid.

In some embodiments, the second structure includes a material selected from the group consisting of polyethylene, polystyrene, polymethyl methacrylate, polyethylene terephthalate, polyurea, foams, textiles, paper, coated paper, kirigami, origami and combinations thereof.

In one aspect, a method includes applying a pressure to the first bladder; changing the volume of the first bladder such that the first structure moves relative to the first conduit.

In some embodiments, wherein applying the pressure includes applying a positive pressure to the first bladder, and changing the volume includes increasing the volume of the first bladder.

In some embodiments, applying the pressure includes applying a negative pressure to the first bladder, and changing the volume includes decreasing the volume of the first bladder.

In some embodiments, the first structure moves toward the first conduit and prevents flow of fluid through the first conduit.

In some embodiments, the first structure moves away from the first conduit and allows flow of fluid through the first conduit.

### BRIEF DESCRIPTION OF THE DRAWINGS

The objects and advantages will be apparent upon consideration of the following detailed description, taken in conjunction with the accompanying drawings, in which like reference characters refer to like parts throughout, and in which:

FIG. 1A shows a normally open valve in an open state, according to certain embodiments.

FIG. 1B shows a normally open valve in a closed state, according to certain embodiments.

FIG. 1C shows a schematic of a normally open valve in an open state, according to certain embodiments.

FIG. 1D shows a schematic of a normally open valve in a closed state, according to certain embodiments.

FIG. 2A shows a normally closed valve in a closed state, according to certain embodiments

FIG. 2B shows a normally closed valve in an open state, according to certain embodiments.

FIG. 2C shows a schematic of a normally closed valve in a closed state, according to certain embodiments.

FIG. 2D shows a schematic of a normally closed valve in an open state, according to certain embodiments.

FIG. 2E shows a normally closed valve with a foam spring in a closed state, according to certain embodiments

FIG. 2F shows a normally closed valve with a foam spring in an open state, according to certain embodiments.

FIG. 3A shows a diagram and truth table for a NOT logic gate, according to certain embodiments.

FIG. 3B shows a schematic of a NOT logic gate with a pulldown resistor, according to certain embodiments.

FIG. 3C shows the pressure-time data for a NOT logic gate, according to certain embodiments.

FIG. 4A shows a diagram and truth table for a NOR logic gate, according to certain embodiments.

FIG. 4B shows a schematic of a NOR logic gate with a pulldown resistor, according to certain embodiments.

FIG. 4C shows the pressure-time data for a NOR logic gate, according to certain embodiments.

FIG. 4D shows a NOR gate with neither input actuated, according to certain embodiments.

FIG. 4E shows a NOR gate with a first input actuated, according to certain embodiments.

FIG. 4F shows a NOR gate with a second input actuated, according to certain embodiments.

FIG. 4G shows a NOR gate with both inputs actuated, according to certain embodiments.

FIG. 5A shows the output signal for a switchable ring oscillator as a function of input, according to certain embodiments.

FIG. 5B shows the output signal over time of a switchable ring oscillator as it switches from a three-ring oscillator to a five-ring oscillator, according to certain embodiments.

FIG. 5C shows a diagram of a switchable ring oscillator functioning as a three-ring oscillator, according to certain embodiments.

FIG. 5D shows a diagram of a switchable ring oscillator functioning as a five-ring oscillator, according to certain embodiments.

FIG. 5E shows a the output signal of a switchable ring oscillator over time, according to certain embodiments.

FIG. 6A shows a cross-section of bistable valve when a bladder is inflated, according to certain embodiments.

FIG. 6B shows a top view of bistable valve when a bladder is inflated, according to certain embodiments.

FIG. 6C shows a cross-section of bistable valve when a bladder is uninflated, according to certain embodiments.

FIG. 6D shows a top view of bistable valve when a bladder is uninflated, according to certain embodiments.

FIG. 6E shows a photograph of a bistable valve, according to certain embodiments.

FIG. 6F shows the pressure in a tube (Pₒᵤₜ) as a function of pressure in the balloon (Pᵢₙ), according to certain embodiments.

FIG. 7A shows the exterior a robot comprising a three-ring oscillator and two SLiT actuators, according to certain embodiments.

FIG. 7B shows the interior of a robot comprising a three-ring oscillator and two SLiT actuators, according to certain embodiments.

FIG. 7C shows an initial position of a robot comprising a three-ring oscillator and two SLiT actuators, according to certain embodiments.

FIG. 7D shows the position of a robot comprising a three-ring oscillator and two SLiT actuators after 60 s of locomotion, according to certain embodiments.

### DETAILED DESCRIPTION

In one aspect, this application describes system to form a pneumatically-actuated transistor logic, comprising a deformable conduit, an extensible bladder disposed at a location along the conduit; a structure in proximity with the bladder and configured to constrain expansion of the bladder; wherein the structure and the bladder are configured to allow flow of fluid through the conduit when the bladder is in a first state and to prevent flow of fluid through the conduit when the bladder is in a second state. In some embodiments, the bladder is actuated to either allow or prevent flow of fluid through the conduit.

In some embodiments, this system enables formation of soft valves or logic gates for soft robots. In some embodiments, soft valves reduce the reliance on electronic components and hard valves in soft robots. In some embodiments, soft valves provide the benefit of simple operation and simple fabrication. Elimination of electronic and hard components provide the further benefit of operation within an MRI machine and sanitization by heat or chemical means, both of which are important for medical applications. Furthermore, soft valves have reduced fragility, increased fatigue resistance, and can operate at high pressures and frequency.

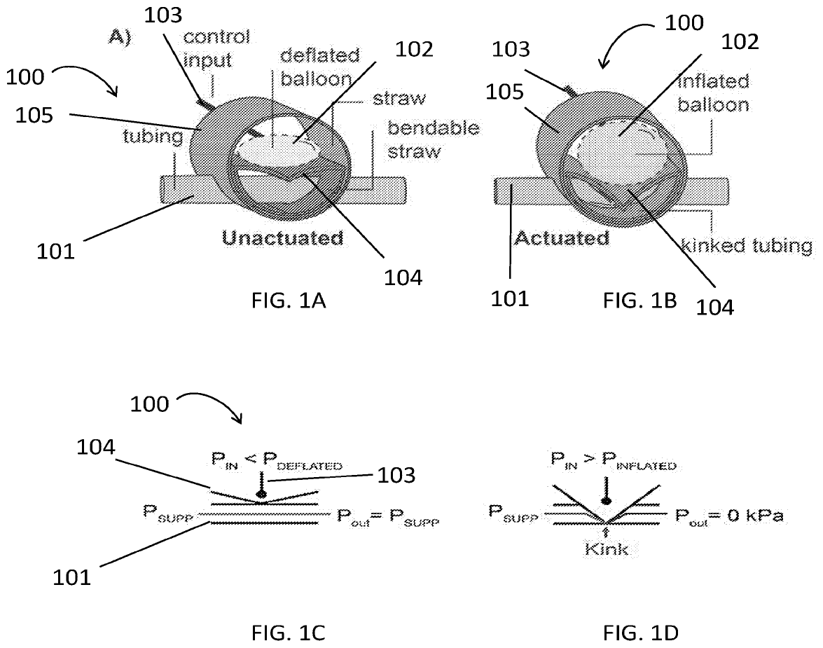

In some embodiments, shown in FIGS. 1A-1D, the system includes a normally open valve. FIG. 1A shows a normally open valve 100 that has not been actuated. In this embodiment, the valve includes a deformable conduit 101, an extensible bladder 102, a control input 103 for actuation of the extensible bladder, and a structure 104 configured to constrain expansion of the bladder 102. In the embodiment shown in FIG. 1A, the structure 103 is disposed between the bladder 102 and the conduit 101 such that fluid can flow through the conduit 101 when the bladder 102 is uninflated. In some embodiments, the valve optionally includes a second structure 105 configured to further constrain expansion of the bladder 102. FIG. 1B shows a normally open valve 100 that has been actuated by supplying a fluid to the bladder 102 via the control input 103. As fluid is supplied to the bladder 102, the bladder 102 inflates, causing the structure 104 to move toward the conduit 101 and preventing fluid flow through the conduit 101. In some embodiments, the bladder 102 is disposed between the structures 104, 105. In some embodiments, the second structure 105 restricts expansion of the bladder 102 such that the bladder 102 moves the structure 104 toward the conduit 101. In some embodiments, the structure 104 squeezes, kinks, or twists the conduit 101, preventing fluid flow.

FIGS. 1C-1D show a schematic of a normally open valve. FIG. 1C shows a valve 101 when the control input 103 supplies a pressure (P_{IN}) less than the inflation pressure of the bladder (P_{DEFLATED}). At this pressure, the bladder exerts insufficient force to press the structure 104 against the conduit 101, and the output pressure (P_{OUT}) of the conduit 101 is equal to the pressure supplied to the conduit (P_{SUPP}). FIG. 1D shows a valve 101 when the control input 103 supplies a pressure (P_{IN}) greater than the inflation pressure of the bladder (P_{INFLATED}). At this pressure, the bladder exerts sufficient force to press the structure 104 against the conduit 101. As a result, fluid is prevented from flowing through the conduit 101, and the output pressure (P_{OUT}) of the conduit 101 is equal to zero. In the embodiment shown in FIG. 1D, the fluid is prevented from flowing through the conduit 101 by a kink in the conduit 101 formed by the structure 104.

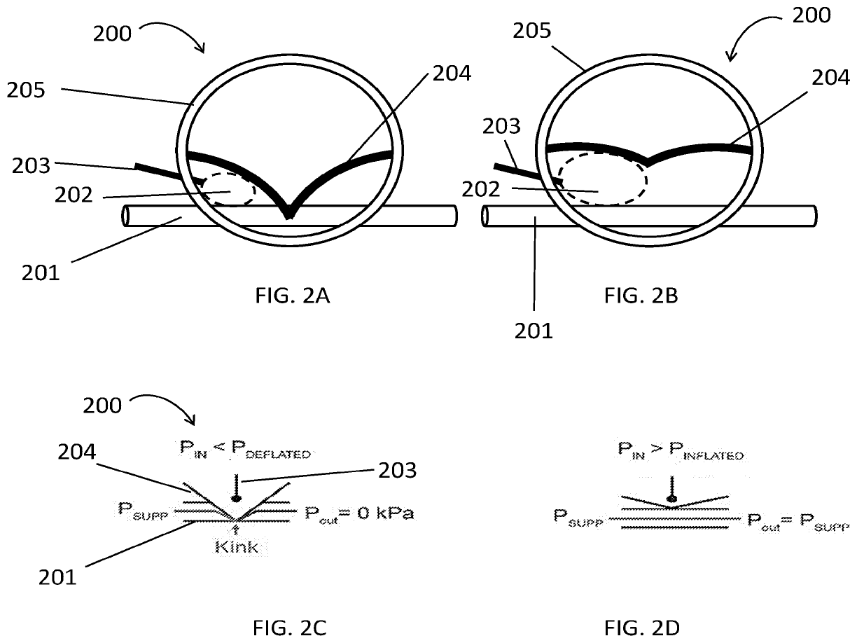

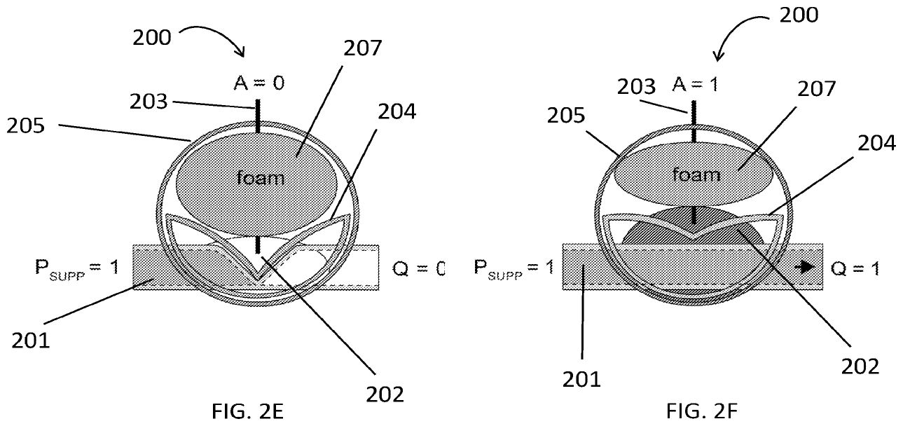

In some embodiments, shown in FIGS. 2A-2F, the system includes a normally closed valve. FIG. 2A shows a normally closed valve 200 that has not been actuated. In this embodiment, the valve includes a deformable conduit 201, an extensible bladder 202, a control input 203 for actuation of the extensible bladder, and a structure 204 configured to constrain expansion of the bladder 202. In the embodiment shown in FIG. 2A, the structure 203 is disposed above the bladder 202 and the conduit 201 such that fluid is prevented from flowing through the conduit 201 when the bladder 202 is uninflated. In some embodiments, the structure squeezes, kinks, or twists the conduit, preventing fluid flow. In some embodiments, the valve optionally includes a second structure 205 configured to further constrain expansion of the bladder 202. FIG. 2B shows a normally closed valve 200 that has been actuated by supplying a fluid to the bladder 202 via the control input 203. As fluid is supplied to the bladder 202, the bladder 202 inflates, causing the structure 204 to move away from the conduit 201 and allowing fluid flow through the conduit 201. In some embodiments, the bladder 202 is disposed between the structures 204, 205. In some embodiments, the second structure 205 restricts expansion of the bladder 202 such that the bladder 202 moves the structure 204 away from the conduit 201.

FIGS. 2C-2D show a schematic of a normally closed valve. FIG. 2C shows a valve 201 when the control input 203 supplies a pressure (P_{IN}) less than the inflation pressure of the bladder (P_{DEFLATED}). At this pressure, the structure 204 is pressed against the conduit 201. As a result, fluid is prevented from flowing through the conduit 201, and the output pressure (P_{OUT}) of the conduit 201 is equal to zero. In the embodiment shown in FIG. 2D, the fluid is prevented from flowing through the conduit 201 a kink in the conduit 201 formed by the structure 204. FIG. 2D shows a valve 201 when the control input 203 supplies a pressure (P_{IN}) greater than the inflation pressure of the bladder (P_{INFLATED}). At this pressure, there is sufficient force to move the structure 204 away the conduit 201, and the output pressure (P_{OUT}) of the conduit 201 is equal to the pressure supplied to the conduit (P_{SUPP}). In the embodiment shown in FIG. 2D, the fluid is prevented from flowing through the conduit 201 by a kink in the conduit 201 formed by the structure 204.

In some embodiments, shown in FIGS. 2E-2F, a normally closed valve includes a foam spring 207. FIG. 2E shows a normally closed valve 200 with a foam spring 207 that has not been actuated. In this embodiment, the valve includes a deformable conduit 201, an extensible bladder 202, a control input 203 for actuation of the extensible bladder, a foam spring 207, and a structure 204 configured to constrain expansion of the bladder 202. In the embodiment shown in FIG. 2E, the structure 203 is disposed above the bladder 202 and the conduit 201, and a foam spring 207 pushes the foam spring 204 toward the conduit 201 such that fluid is prevented from flowing through the conduit 201 when the bladder 202 is uninflated. In some embodiments, the structure squeezes, kinks, or twists the conduit, preventing fluid flow. In some embodiments, the valve optionally includes a second structure 205 configured to further constrain expansion of the bladder 202. FIG. 2F shows a normally closed valve 200 with a spring 207 that has been actuated by supplying a fluid to the bladder 202 via the control input 203. As fluid is supplied to the bladder 202, the bladder 201 inflates, the bladder 202 compresses the foam spring 207, causing the structure 204 to move away from the conduit 201 and allowing fluid flow through the conduit 201. In some embodiments, the bladder 202 is disposed between the structures 204, 205. In some embodiments, the second structure 205 restricts expansion of the bladder 202 such that the bladder 202 moves the structure 204 away from the conduit 201. In some embodiments, the foam spring 207 is disposed between the structures 204, 205. In some embodiments, the second structure 205 restricts extension of the foam spring 207 such that the foam spring moves the structure 204 toward from the conduit 201.

In some embodiments, actuation of the valve or logic gate is caused by a force differential between the bladder and the conduit. In some embodiments, in a normally open valve, fluid flow is prevented when the force exerted by the structure via actuation of the bladder exceeds the force exerted by the conduit. In this embodiment, when the valve is actuated, the force exerted by the bladder is sufficient to move the structure toward the conduit and into a position that prevents fluid flow through the channel. In some embodiments, in a normally closed valve, fluid flow is allowed when the force exerted by the conduit exceeds the force exerted by structure. In this embodiment, when the valve is actuated, the force exerted by the bladder is sufficient to move the structure away from the conduit and into a position that allows fluid flow through the channel.

In some embodiments, actuation of the valve is caused by a pressure differential between the bladder and the conduit. In some embodiments, in a normally open valve, fluid flow is prevented when the pressure in the bladder exceeds the pressure in the conduit. In this embodiment, when the valve is actuated, the pressure in the bladder is sufficient to move the structure toward the conduit and into a position that prevents fluid flow through the channel. In some embodiments, in a normally closed valve, fluid flow is allowed when the pressure in the conduit exceeds the force exerted by the structure. In this embodiment, when the valve is actuated, the pressure in the bladder is sufficient to move the structure away from the conduit and into a position that allows fluid flow through the channel.

In some embodiments, actuation of the valve is caused by applying a pressure to the bladder. In some embodiments, the pressure is a positive pressure. In some embodiments, applying a positive pressure to the bladder causes inflation of the bladder. In some embodiments, applying a positive pressure to the bladder includes delivering a fluid to the bladder via a control input. In some embodiments, a fluid is a liquid, gas, or hydrogel. In some embodiments, applying a positive pressure to the bladder includes applying a vacuum to the space surrounding the bladder. In some embodiments, the pressure is a negative pressure. In some embodiments, applying a negative pressure to the bladder causes deflation of the bladder. In some embodiments, applying a negative pressure to the bladder includes applying a vacuum to the bladder via a control input. In some embodiments, applying a negative pressure to the bladder includes delivering a fluid to the space surrounding the bladder. In some embodiments the magnitude of the pressure is up to 1000 kPa. In some embodiments, the magnitude of the pressure is 100 kPa, 200 kPa, 300 kPa, 400 kPa, 500 kPa, 600 kPa, 700 kPa, 800 kPa, 900 kPa, 1000 kPa, or any value in between.

In some embodiments, actuation of the valve is enabled by a stiffness differential between the conduit and the structure. In some embodiments, the structure is stiffer than the conduit such that when structure is in contact with the conduit, the structure causes the conduit to deform, preventing flow of fluid through the conduit.

In some embodiments, the structure includes a feature that concentrates the force of the structure on the conduit. In some embodiments, a stress concentrating feature causes the force exerted by the bladder to overcome the force exerted by the conduit. In some embodiments, a stress concentrating features causes the structure to exert a force that is between 5 and 100 times greater than the force exerted by the bladder. In some embodiments, the force exerted by the structure is 5, 10, 15, 20, 25, 30, 40, 50, 60, 70, 80, 90, or 100 times greater than the force exerted by the bladder. In some embodiments, a stress concentrating feature causes the conduit to deform more readily when in contact with the structure. In some embodiments the force concentrating features is an edge, a point, and combinations thereof. In some embodiments, the conduit is looped around or within the structure. In some embodiments, the conduit is folded around or within the structure.

In some embodiments, fluid flow is prevented by a structure squeezing, kinking, or twisting the conduit. In some embodiments, these operations push the walls of the conduit together or reduce the effective cross-section of the conduit. In some embodiments, the conduit is squeezed and the walls of the conduit move together, preventing fluid flow. In some embodiments, the conduit is kinked or bent, preventing fluid flow. In some embodiments, the conduit is twisted about its long axis, preventing fluid flow.

In some embodiments, actuation of a valve is reversible. In some embodiments, a valve returns to its unactuated state. In some embodiments, a valve is actuated when a pressure is applied and the valve returns to its unactuated state when the pressure is no longer applied. In some embodiments, a valve is actuated when a pressure is applied and the valve returns to its unactuated state when an opposite pressure is applied. For example, in some embodiments, a valve is actuated by applying a positive pressure and the valve returns to its unactuated state by applying a negative pressure. Alternatively, in some embodiments, a valve is actuated by applying a negative pressure and the valve returns to its unactuated state by applying a positive pressure.

In some embodiments, the system includes a mechanism to restore the valve to its unactuated state. Such a mechanism can be active or passive. In some embodiments, the system includes a pulldown resistor that allows a bladder to deflate in an unactuated state. In some embodiments, a pulldown resistor is a tube connected or hole in the bladder which causes loss of fluid from the bladder. In these embodiments, a bladder deflates if not supplied with fluid through a control input. In some embodiments, the system includes a second bladder configured to return the structure to its original position when the second bladder is actuated. In some embodiments, the system includes a foam spring is configured to return the structure to its original position. In some embodiments, a foam spring is configured to push the structure towards or away from the conduit.

In some embodiments, the system includes a mechanism to assist in actuation of the valve. Such a mechanism can be active or passive. In some embodiments, the system includes a pulldown resistor that reduces flow of fluid through the conduit as the bladder inflates. In some embodiments, a pulldown resistor is a tube connected or hole in the conduit which causes loss of fluid from the conduit. In these embodiments, the bladder prevents fluid flow at a lower bladder inflation pressure because some pressure in the conduit is lost via the pulldown resistor.

### Materials

In some embodiments, the bladder includes an extensible material. In some embodiments, the bladder in elastomeric. In some embodiments, the bladder includes strain-limiting components in regions of the bladder such that the bladder expands preferentially in one direction. In some embodiments, the bladder includes a polymer, foam, or textile, or any combination thereof. Non-limiting examples of textiles include fabrics and fabrics or textiles with thermo-coatings and combinations thereof. Non-limiting examples of foams includes coated foams. Non-limiting examples of polymers include vulcanized rubber, silicone elastomer, latex, polyurethanes, or combinations thereof. In some embodiments, the bladder is a thermoplastic polyurethane (TPU) such as Stretchlon 200 Bagging Film. In some embodiments, the bladder includes combinations of foam and elastomeric polymers an elastomeric bladder that surrounded by constraining foam.

In some embodiments, the geometry and materials of the bladder are selected to optimization the actuation or inflation time of the bladder. For example, a more compliant bladder material inflates more rapidly and deflates less rapidly than a stiffer bladder material, resulting in shorter actuation time. For example, a smaller bladder inflates and deflates more rapidly than a larger balloon.

In some embodiments, the bladder can withstand pressures of up to 1000 kPa. In some embodiments the magnitude of the pressure is up to 1000 kPa. In some embodiments, the magnitude of the pressure is 100 kPa, 200 kPa, 300 kPa, 400 kPa, 500 kPa, 600 kPa, 700 kPa, 800 kPa, 900 kPa, 1000 kPa, and any value in between.

In some embodiments, the conduit includes a flexible material. In some embodiments, the conduit is capable of being kinked, squeezed, or twisted. In some embodiments, the conduit is non-extensible. In some embodiments, the conduit recovers deformation caused by the structure and returns to its initial configuration after actuation. In some embodiments, the conduit recovers deformation by a restoring force. In some embodiments, the conduit recovers elastically. In some embodiments, the conduit includes a polymer, foam, or textile, or any combination thereof. Non-limiting examples of foams include high density foam and compressed polyester. Non-limiting examples of textiles include coated and laminated fabrics such as Diatex M28018 PS PU M12. Non-limiting examples of polymers include poly vinyl chloride, polyurethane, nylon, polyethylene, polypropylene, polytetrafluoroethylene, or combinations thereof. In some embodiments, the conduit includes a polytetrafluoroethylene film.

In some embodiments, the structure configured to constrain expansion of the bladder is non-extensible and avoids permanent deformation. In some embodiments, the structure recovers deformation caused by actuation and returns to its initial position after actuation. In some embodiments, the structure recovers deformation by a restoring force. In some embodiments, the structure recovers elastically. In some embodiments, the structure is rigid. In some embodiments, the structure is stiffer than the conduit. In some embodiments, the structure includes polymer, foam, textile, paper or any combination thereof. Non-limiting examples of polymers include polyethylene, polystyrene, polymethyl methacrylate, polyethylene terephthalate, or combinations thereof. In some embodiments, polyurea spray coatings could be used to modify commercially available foams and change their mechanical attributes. Non-limiting examples of paper structures include coated papers, origami structures, kirigami structures, and combinations thereof.

### NOT Gates

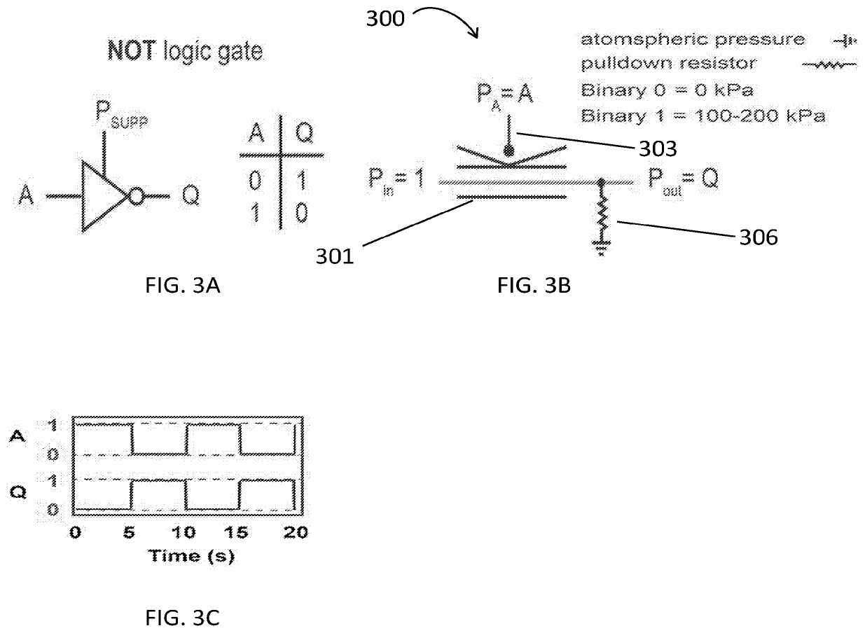

In some embodiments, a system to form a pneumatically-actuated transistor logic includes a NOT gate or inverter. In some embodiments, actuating a valve prevents flow through a conduit. In this embodiment, binary values of one and zero are assigned to a pressure P and a pressure of zero, respectively. In some embodiments, shown in FIGS. 3A-3C, the NOT gate includes a normally open valve. FIG. 3A shows a diagram and a truth table for a NOT gate. In the diagram, A represents the input to the bladder of a normally open valve, P_{SUPP} represents the pressure supplied to a conduit, and Q represents the output of the conduit. If no pressure is supplied to the bladder (A=0), then fluid is allowed to flow through the conduit and the output pressure is equal to the supplied pressure (Q=1). If a pressure P is applied to the bladder (A=1), then fluid is prevented from flowing through the conduit and the output pressure is zero (Q=0). FIG. 3B shows a schematic of a NOT gate. In this embodiment, an input pressure (P_{IN}) is applied to the conduit 301 and a pressure (P_{A}) is applied to the bladder through a control input 303. When P_{A} is not applied (A=0), fluid flows through the conduit, and the output pressure (P_{OUT}) is equal to the input pressure (Q=1). When P_{A} is applied (A=1), fluid is prevented from flowing through the conduit, and the output pressure (P_{OUT}) is zero (Q=0). In some embodiments, the NOT gate includes a pulldown resistor 306 on the conduit 301 that assists in actuating the valve. FIG. 3C shows the binary values of A and Q over time. At times when pressure is applied to the bladder (A=1), the output pressure is zero (Q=0), and at times when no pressure is applied to the bladder (A=0), the output pressure is equal to the input pressure (Q=1).

### NOR Gates

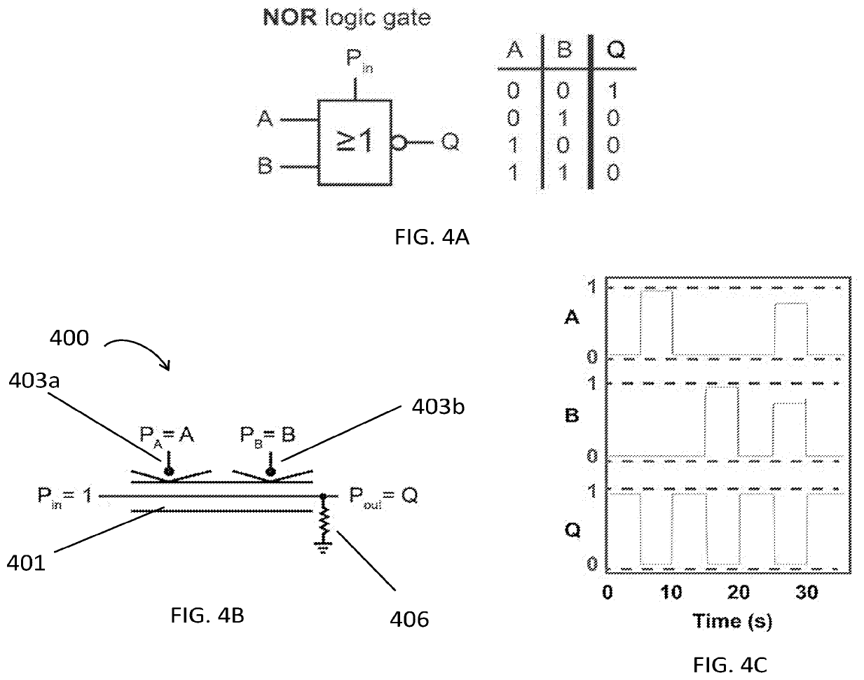

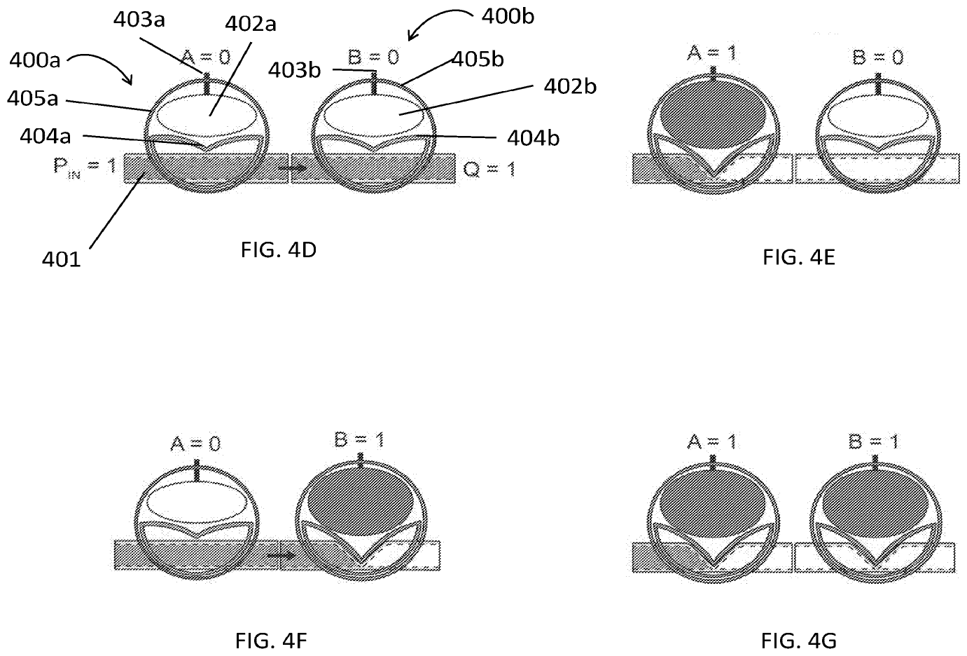

In some embodiments, a system to form a pneumatically-actuated transistor logic includes a NOR gate. In some embodiments, shown in FIGS. 4A-4G, the NOR gate includes two normally open valves located at two locations in series along a conduit. In some embodiments, actuating one or both of the valves prevents fluid flow through the conduit. FIG. 4A shows a diagram and a truth table for a NOR gate. In the diagram, A represents the input to a first bladder of a first normally open valve, B represents the input to a second bladder of a second normally open valve, P_{IN} represents the pressure supplied to a conduit, and Q represents the output of the conduit. If no pressure is supplied to the first or second bladder (A=0 AND B=0), then fluid is allowed to flow through the conduit and the output pressure is equal to the supplied pressure (Q=1). If a pressure P is applied to at least one of the first and second bladders (A=1, B=1, or A=1 AND B=1) then fluid is prevented from flowing through the conduit and the output pressure is zero (Q=0). FIG. 4B shows a schematic of a NOR gate. In this embodiment, an input pressure (P_{IN}) is applied to the conduit 401, a pressure (P_{A}) is applied to a first bladder through a control input 403a, and a pressure (P_{B}) is applied to a second bladder through a control input 403b. When P_{A} and P_{B} are not applied (A=0 AND B=0), fluid flows through the conduit, and the output pressure (P_{OUT}) is equal to the input pressure (Q=1). When one or both of P_{A} and P_{B} are applied (A=1, B=1, or A=1 AND B=1), fluid is prevented from flowing through the conduit, and the output pressure (P_{OUT}) is zero (Q=0). In some embodiments, the NOT gate includes a pulldown resistor 406 on the conduit 401 that assists in actuating the valve. FIG. 4C shows the binary values of A, B and Q over time. At times when pressure is applied to the first or second bladder (A=1, B=1, or A=1 AND B=1), the output pressure is zero (Q=0) and at times when no pressure is applied to the first or second bladder (A=0 AND B=0), the output pressure is equal to the input pressure (Q=1).

FIGS. 4D-4G show four different scenarios for a NOR gate. In this embodiment, the NOR gate includes two normally open valves 400a, 400b in series along a conduit 401. In this embodiment, each valve includes a bladder 402a, 402b, a control input 403a, 403b for the bladder, and a structure configured to constrain inflation of the bladder 404a, 404b. Each valve may further include a second structure that constrains inflation of the bladder 405a, 405b. FIG. 4D shows a NOR gate when neither input control 403a, 403b supplies pressure to the bladders 402a, 402b (A=0, B=0). Under this condition, the structures 404a, 404b allow fluid flow through the conduit 401, and the output pressure is equal to the input pressure (Q=1). FIG. 4E shows a NOR gate when the first input control 403a supplies pressure to the first bladder 402a, but the second input control 403b supplies no pressure to the second bladder 402b (A=1, B=0). As shown in FIG. 4E, the first bladder 402a pushes the first structure 404a toward the conduit 401, preventing flow (Q=0). FIG. 4F shows a NOR gate when the first input control 403a, supplies no pressure to the first bladder 402a, but the second input control 403b supplies pressure to the second bladder 402b (A=0, B=1). As shown in FIG. 4F, the second bladder 402b pushes the second structure 404b toward the conduit, preventing flow (Q=0). FIG. 4G shows a NOR gate when the first input control 403a supplies pressure to the first bladder 402a and the second input control 403b supplies pressure to the second bladder 402b (A=1, B=1). As shown in FIG. 4G, the first bladder 402a pushes the first structure 404a toward the conduit 401, and the second bladder 402b pushes the second structure 404b toward the conduit 401, preventing flow (Q=0).

NAND gates

In some embodiments, a system to form a pneumatically-actuated transistor logic includes a NAND gate. In some embodiments, the NAND gate includes a first and second conduit that merge to form a third conduit, a first normally open valve located on the first conduit, and a second normally open valve located on the second conduit. In some embodiments, actuating both of the valves prevents fluid flow through the third conduit, and otherwise fluid is allowed to flow through the third conduit. A represents the input to a first bladder of a first normally open valve, B represents the input to a second bladder of a second normally open valve, P_{IN} represents the pressure supplied to the first or second conduit, and Q represents the output of the third (merged) conduit. If no pressure is supplied to the first or second bladder (A=0 AND B=0), then fluid is allowed to flow through the third conduit and the output pressure is equal to the supplied pressure (Q=1). If a pressure P is applied to only one of the first and second bladders (A=1 AND B=0; A=0 AND B=1) then fluid is allowed to flow through the third conduit and the output pressure equal to the supplied pressure (Q=1). If a pressure P is applied to both bladders (A=1 AND B=1), then fluid is prevented from flowing through the third conduit and the output pressure is zero (Q=0).

### Ring Oscillators

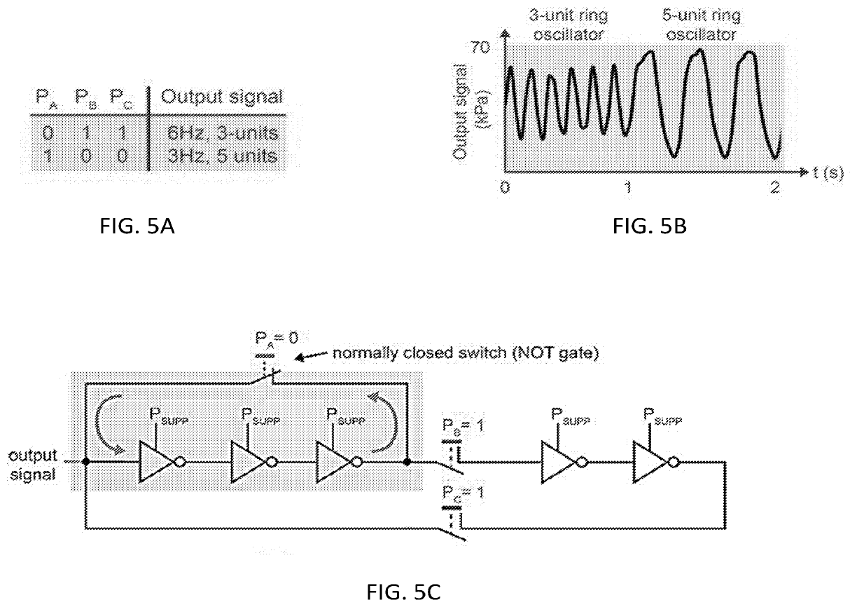

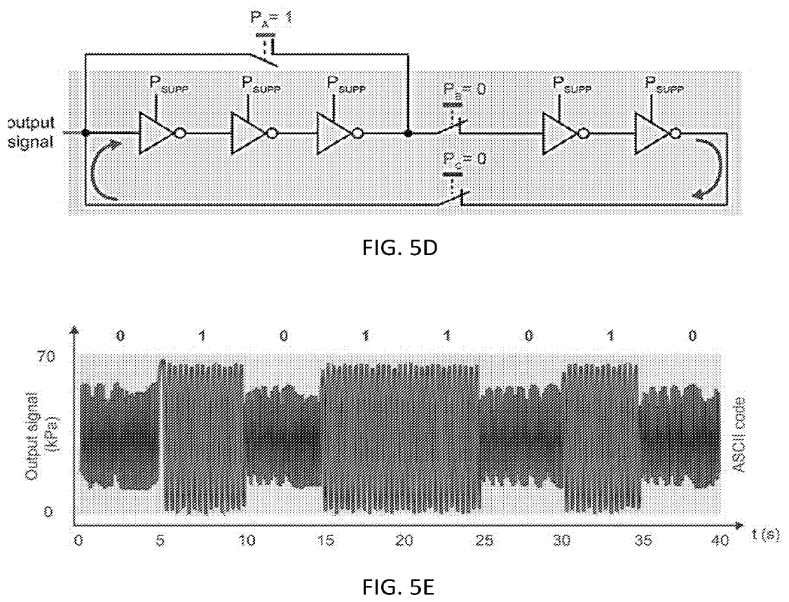

In some embodiments, shown in FIGS. 5A-5E, a system to form a pneumatically-actuated transistor logic includes a ring oscillator. In some embodiments, a ring oscillator converts a constant input into a time-varying output. In some embodiments ring oscillator includes a plurality of NOT gates or inverters in series such that the output of the conduit of a first NOT gate serves as the input control of the bladder in a second NOT gate. In some embodiments, the output of the n^{th} NOT gate serves as the input control of the n^{th}+1 NOT gate. In an embodiment with N NOT gates, the output of the last (N^{th}) NOT gate serves as the input of the first NOT gate. In some embodiments, this configuration results in alternating inflation and deflation of the bladders associated with each NOT gate. In some embodiments, a ring oscillator converts a constant input to a periodic, oscillating output. In some embodiments, a ring oscillator operates with an output at the following frequency f

$$f = \frac{1}{2 * T * n}$$

where Tis the time delay for a single inverter and n is the number of inverters in series. In some embodiments, an oscillator includes three or more NOT gates. In some embodiments, a ring oscillator has any odd number of NOT gates. In some embodiments, an odd number of NOT gates leads to instability and therefore oscillation.

In some embodiments, a system to form a pneumatically-actuated transistor logic includes a switchable oscillator. In some embodiments, a switchable oscillator controls the frequencies of the inverters. In some embodiments, a switchable oscillator controls the number of inverts being actuated. In some embodiments, a switchable oscillator includes five NOT gates in series and three normally open valves (i.e., normally closed switches). In this embodiment, the normally open valves are located between the third and fourth NOT gates (P_{B}), the fifth and first NOT gates (P_{C}), and the third and first NOT gates (P_{A}). As shown in FIG. 5A, when valves B and C are actuated (P_{B}=1, P_{C}=1) but valve A is not actuated (P_{A}=0), the switch functions as a 3-unit switch with a higher frequency. In contrast, when the valves B and C are not actuated (P_{B}=0, P_{C}=0) but the valve A is actuated (P_{A}=1), the switch functions as a 5-unit switch with a lower frequency. FIG. 5B shows the output signal over time of a switchable ring oscillator as it switches from a three-ring oscillator to a five-ring oscillator. FIG. 5C shows a diagram of a switchable ring oscillator when the valves B and C are actuated (P_{B}=1, P_{C}=1) but the valves A is not actuated (P_{A}=0), and the oscillator functions as a three-ring oscillator. FIG. 5D shows a diagram of a switchable ring oscillator when the valves B and C are not actuated (P_{B}=0, P_{C}=0) but the valves A is actuated (P_{A}=1), and the oscillator functions as a five-ring oscillator. FIG. 5E shows a the output signal of a switchable ring oscillator over time.

### Bistable Valve

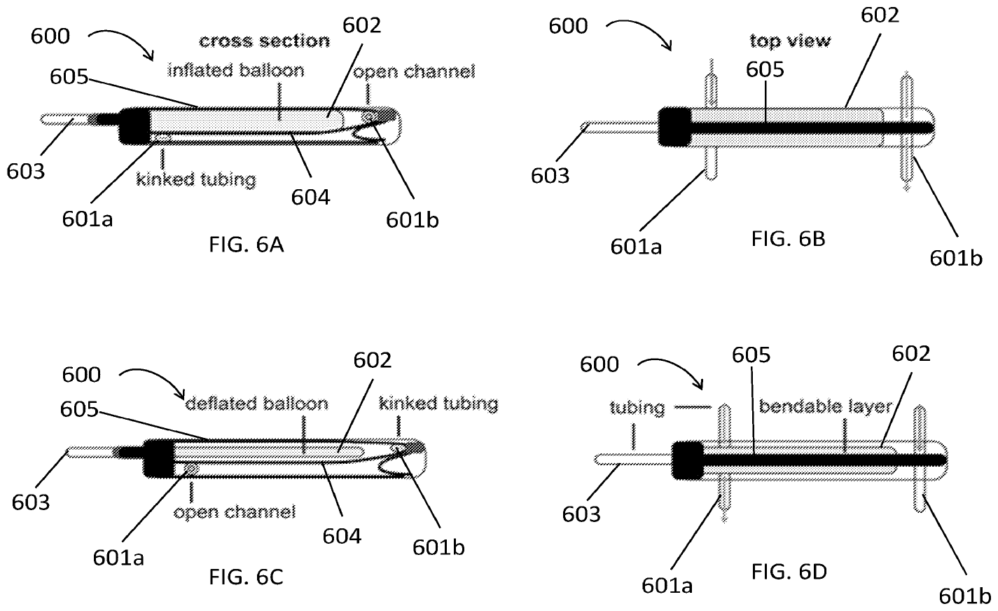

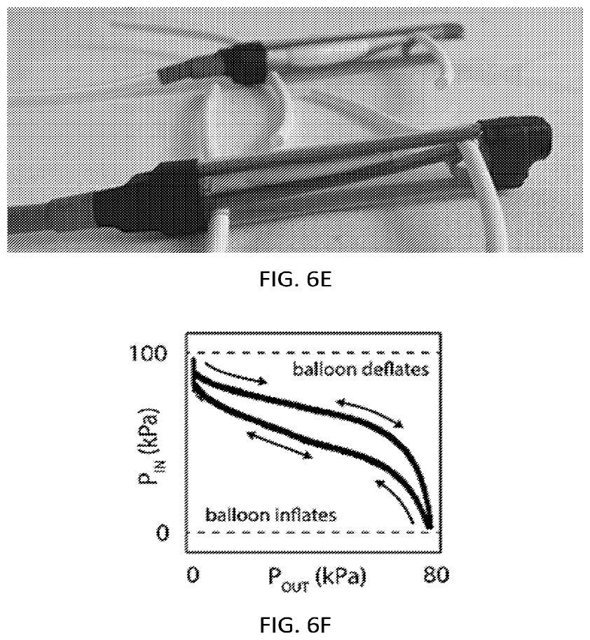

In some embodiments, shown in FIGS. 6A-6F, a system to form a pneumatically-actuated transistor logic includes a bistable or two-state valve for controlling flow in two conduits via actuation of a single bladder. In some embodiments, a bistable is stable in an actuated state and in an unactuated state. In some embodiments, a bistable valve allows fluid flow in one conduit when the bladder is actuated and allows fluid flow in the other conduit when the bladder is not actuated. As shown in FIGS. 6A-6B, a cross-section and top view of a bistable valve 600, when the input control 603 supplies pressure to the bladder 602, structures 604, 605 constrain expansion of the bladder 602 so that one structure 604 is moved toward the first conduit 601a and away from the second conduit 601b. As a result, when the bladder 602 is inflated, fluid flow is allowed through the second conduit 601b but prevented through the first conduit 601a. In contrast, as shown in FIGS. 6C-6D, when the input control 603 no longer supplies pressure to the bladder 602 and the bladder deflates, structure 604 is no longer pushed toward the first conduit 601a and returns to a position where the structure is pushed toward the second conduit 601b. As a result, fluid flow is allowed through the first conduit 601a but prevented through the second conduit 601b. FIG. 6E shows a photograph of such a bistable valve. FIG. 6F shows the output pressure in the first conduit (P_{OUT}) as a function of the input control pressure (P_{IN}). As the input control pressure decreases and the bladder deflates, the output pressure in the second conduit increases. As the input control pressure increases and the bladder inflates, the output pressure in the second conduit decreases until it reaches zero and flow through the second conduit is prevented.

### Applications

In some embodiments, pneumatically-actuated transistor logic can be used in medical applications. In some embodiments, pneumatically-actuated transistor logic actuates a soft robotic system. In some embodiments, pneumatically-actuated transistor logic actuates separate components of a soft robotic system independently. In some embodiments, a soft robotic system uses gas inputs available in a hospital. In some embodiments, a soft robotic system is used in an Mill system. In some embodiments, a soft robotic system is used for mechanotherapy devices in healthcare.

In some embodiments, a soft robotic system uses an incompressible or compressible fluid for hydraulic lifting. In these embodiments, pressure is converted according to Pascal's law to lift an object:

Δp=ρg(Δh)

where Δp is the hydrostatic pressure, p is the fluid density, g is the acceleration due to gravity, and Δh is the height of the fluid. In some embodiments, a soft robotic system such as an airjack can lift tons of weight by application of a few kPa. In some embodiments, a soft robotic system is used to lift patients.

### Examples

Certain embodiments will now be described in the following non-limiting examples.

### Tube-Balloon Logic Gates

A tube-balloon logic gate was made from low-cost materials (a balloon, drinking straw, and polyvinyl chloride tubing). A tube-balloon logic device 100 was made using two straws (e.g., one boba straw with a diameter of approximately 15 mm cut into two shorter straws) for the constraining structures 104, 105, a balloon (e.g. a twisting balloon for forming balloon animals) for the bladder 102, and polyvinyl chloride (PCV) tubing for the conduit 101. The manufacture of the device included punching holes into both straws as inlet for the PVC tubing 101; folding one straw into a bendable layer 104; inserting the bendable layer into the outer straw 105; feeding the PVC tubing 101 through both straws (bendable layer and outer straw); and inserting the balloon 102 inside the outer straw such that it lays in between the outer straw 105 and the bendable layer 104. As shown in FIG. 1A, the outer straw 105 acted as housing for the inner straw; the inner straw 104 is acted bendable layer that cuts off the tubing 101, if pressed onto by an inflatable balloon 102. The outer straw 105 constrained inflation of the balloon 102, causing the inner straw 104 to move toward the tubing 101 and cut off flow through the tubing by kinking the tubing. The balloon is a mechanical equivalent of an electric capacitor. It charges (inflates) until it reaches saturation (equilibrates with the applied pressure). The balloon is constrained in its volumetric expansion by the outer straw. A balloon of large volume requires a longer time to deflate for a given discharge load (pneumatic pull-down resistor), than a balloon of smaller volume. Hence, balloon volume impacts switching frequency. This tube balloon logic gate has been tested for gauge pressures up to 200 kPa.

### Switchable Ring Oscillator

As shown in FIGS. 5A-5E, a three-ring oscillator that can be extended to a five-ring oscillator during operation was developed. As shown, in FIGS. 5C-5D, five tube balloon logic devices (NOT gates) were interconnected in series and additional tube balloon logic devices (normally closed switches) were placed between the third and fourth inverter (P_{B}), the fifth and the first inverter (P_{C}), and the third and the first inverter (P_{A}). To switch between three-ring and five-ring oscillator configurations, these three normally-closed-switches can be actuated. If P_{A}=0 and P_{B}=P_{C}=1, a three-ring oscillator is configured; if P_{A}=1 and P_{B}=P_{C}=0, a five-ring oscillator is configured. As shown in FIG. 5B, a frequency of 6 Hz and an amplitude of 50 kPa was observed for the three-ring-oscillator, and while a frequency of 3 Hz and an amplitude of 70 kPa was observed for the five-ring-oscillator. In this oscillator, the time delay for each inverter was 30 ms. As shown in FIG. 5E, a change from a three-ring to a five-ring-oscillator caused an audio output that varied in sound (pressure amplitude and frequency). The change in pressure amplitude is explained by the characteristics of the balloons that are integrated inside the tube balloon logic devices. If the time between inflation and deflation of balloons increases (five-ring oscillators oscillate at lower frequencies than three ring oscillators), the balloons have time to inflate to a greater extent, hence, equilibrate at higher pressures than a lower numbered ring oscillator.

### Robot for Locomotion

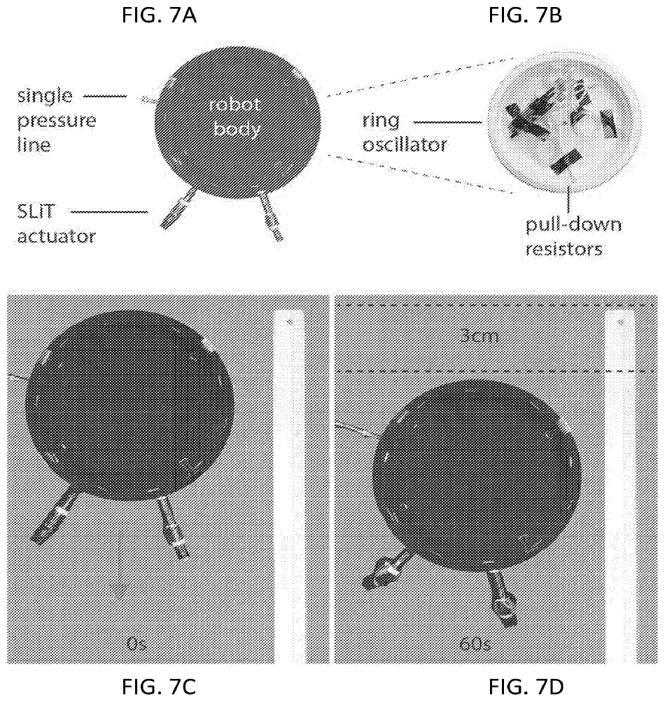

A simple robot, shown in FIGS. 7A-7D was developed by integrating a three-ring oscillator made from tube balloon logic devices with two slit-in-tube (SLiT) actuators and placing them in between two cardboard layers. A SLiT actuator includes a tube of a non-extensible material having parallel cuts or slits and an elastomeric tube disposed within the tube of non-extensible material. When the elastomeric tube is inflated, the non-extensible material with slits constrains the expansion of the elastomeric tube. In this robot, the slits are oriented parallel to a vertical axis and the elastomeric tube inflates, the length of the tube contracts.

The two (SLiT) actuators were temporally sequenced, leading to one-directional locomotion. The robot is powered from a single pressure line and moved a distance of 3 centimeters in 60 seconds. The robot includes cardboard, straws, tubes, and balloons making it to a low-cost robot with integrated control. The three-ring oscillator has 3 outputs, one after each NOT gate. Two outputs are attached to SLiT actuators, and then cause sequenced actuation. The third oscillator output disconnected or “closed”. Alternatively, several actuators could be connected to a single oscillator output. In this case, all actuators of one oscillatory output are actuated simultaneously.

It will be appreciated that while one or more particular materials or steps have been shown and described for purposes of explanation, the materials or steps may be varied in certain respects, or materials or steps may be combined, while still obtaining the desired outcome. Additionally, modifications to the disclosed embodiment and the invention as claimed are possible and within the scope of this disclosed invention.

1-51. (canceled)

52. A system to form a pneumatically-actuated transistor logic, comprising
a first deformable conduit;
a first extensible bladder disposed at a first location along the first deformable conduit;
a first structure in proximity with the first extensible bladder and configured to constrain expansion of the first extensible bladder;
wherein the first structure and the first extensible bladder are configured to allow flow of fluid through the first deformable conduit when the first extensible bladder is in a first state and to prevent flow of fluid through the first deformable conduit when the first extensible bladder is in a second state.

53. The system of claim 52, wherein the first state of the first extensible bladder is an inflated state and the second state of the first extensible bladder is an uninflated state; or wherein the first state of the first extensible bladder is an uninflated state and the second state of the first extensible bladder is an inflated state.

54. The system of claim 52, further comprising a first input to the first extensible bladder.

55. The system of claim 52, wherein the system is configured to apply a first pressure to the first extensible bladder to actuate between the first state of the first extensible bladder and the second state of the first extensible bladder.

56. The system of claim 52, further comprising a pulldown resistor.

57. The system of claim 52, further comprising a foam spring.

58. The system of claim 52, wherein the first structure is configured to deform the first deformable conduit when the first extensible bladder is in the second state.

59. The system of claim 52, wherein the first structure is stiffer than the first deformable conduit.

60. The system of claim 52, wherein the first structure comprises a force concentrating feature.

61. The system of claim 52, wherein the first extensible bladder is elastomeric.

62. The system of claim 52, wherein the first structure is non-extensible or rigid.

63. The system of claim 52, wherein the first deformable conduit is non-extensible.

64. The system of claim 52, further comprising
a second deformable conduit, wherein the first extensible bladder is disposed at a second location along the second deformable conduit;
wherein the first structure and the first extensible bladder are configured to prevent flow of fluid through the second deformable conduit when the first extensible bladder is in a first state and to allow flow of fluid through the second deformable conduit when the first extensible bladder is in a second state.

65. The system of claim 64, wherein the first structure is configured to deform the second deformable conduit when the first extensible bladder is in the first state.

66. The system of claim 64, wherein the first structure is stiffer than the second deformable conduit.

67. The system of claim 64, wherein the second deformable conduit is non-extensible.

68. The system of claim 52, further comprising
a second extensible bladder is disposed at a second location along the first deformable conduit;
a second structure in proximity with the second extensible bladder and configured to constrain expansion of the second extensible bladder;
wherein the second structure and the second extensible bladder are configured to allow flow of fluid through the first deformable conduit when the second extensible bladder is in a first state and to prevent flow of fluid through the first deformable conduit when the second extensible bladder is in a second state.

69. The system of claim 68, wherein the first state of the second extensible bladder is an inflated state and the second state of the second extensible bladder is an uninflated state; or wherein the first state of the second extensible bladder is an uninflated state and the second state of the second extensible bladder is an inflated state.

70. The system of claim 68, further comprising a second input to the second extensible bladder.

71. The system of claim 68, wherein the system is configured to apply a second pressure to the second extensible bladder to actuate between the first state of the second extensible bladder and the second state of the second extensible bladder.

72. The system of claim 68, wherein the second structure is configured to deform the first deformable conduit when the second extensible bladder is in the second state.

73. The system of claim 68, wherein the second structure is stiffer than the first deformable conduit.

74. The system of claim 68, wherein the second extensible bladder is elastomeric.
